(19) United States
(12) Patent Application Publication
(10) Pub. No.: US 2018/0247573 A1
(43) Pub. Date: Aug. 30, 2018

(54) DEVICE FOR DISPLAYING A VARIABLE INSTRUCTION BY AN INSTRUCTION ROAD SIGN

(71) Applicant: AXIMUM, Magny Les Hameaux (KR)

(72) Inventors: Franck GAUTHIER, METTRAY (FR); Jean-Louis BOURDAIS, PARCAY MESLAY (FR); Mickaël CADOUR, ROUZIERS DE TOURAINE (FR)

(21) Appl. No.: 15/757,558

(22) PCT Filed: Aug. 30, 2016
(86) PCT No.: PCT/FR2016/052150

§ 371 Date: Mar. 5, 2018

(30) Foreign Application Priority Data
Sep. 4, 2015 (FR) 1558194

(51) Int. Cl. G09F 11/23; G09F 7/18; H01L 31/02

(52) U.S. Cl. CPC G09F 11/23; G09F 2007/1878; H01L 31/02002; G09F 7/18

(57) ABSTRACT

Disclosed is a device for displaying an instruction by a B14 or equivalent panel having a flat circular front plate with an instruction display area. In the case of a B14 panel, the digital value displayed can be modified by changing at least one modifiable character. The display area includes an opening and the panel includes at least one flat movable support on which the substitution figures are represented, the front plate and the flat movable support being parallel to each other, the flat movable support being included in the template of the front plate, each substitution figure being provided by an actuator facing the opening, the flat movable support or at least one of the flat movable support being a rotatable disc, the centre of the rotatable disc being laterally offset with respect to the centre of the circular front plate. The device is autonomous with photovoltaic power supply.

### TECHNICAL FIELD TO WHICH THE INVENTION RELATES

The present invention generally relates to the variable display devices using a B-series codified instruction road sign, in particular of the B14 regulatory speed-limitation road sign type. It hence relates in particular to the traditional B14-codified road sign of the free-standing metallic type and displaying the speed limit in a white-background display area at the centre of a red-colour ring. However, it may be applied to other types of instruction road signs and to other fields than the road traffic and, for example, to the field of rail or fluvial/maritime signs but with codifications or standardizations adapted to the concerned domain.

### TECHNOLOGICAL BACK-GROUND

Variable road speed-limitation luminous display systems are known. They have the same regulatory force as the traditional B14 fixed-display metallic road signs on which the indicated speed is painted, printed, screen printed or added, in particular on an adhesive film. However, used to the traditional B14 fixed-display metallic road signs, the motorists are tempted to consider with less attention the variable luminous road signs. Moreover, along certain traffic lane sections having both luminous road signs and traditional fixed road signs, the presence of a sequence of contradictory speed-limitation information displayed on the luminous road signs and on the fixed road signs may generate lacks of understanding from the drivers and generate dangerous behaviours such as untimely accelerations and decelerations.

It is hence interesting as regards the security and the respect of speed limitations to use conventional road signs. However, these conventional road signs are of the fixed display type, which prevents or limits the use thereof in areas in which the speed limit must be frequently modified due to the fact that it would be necessary to change them.

Variable instruction road signs are known from the documents WO-86/06860A1, US-5.493.292A and JP-H07-3730A. These road signs have a rotatable part that is centred on the circular front plate of the road sign.

### OBJECT OF THE INVENTION

Generally, the invention relates to a device for displaying an instruction using an instruction road sign having an aspect according to the B codification or equivalent, the road sign including a flat, circular front plate with a front, display face and a rear face, opposite to the front face, the front face of said road sign displaying substantially at the centre thereof, in an instruction display area, an instruction consisted of several symbols of codified size and typography.

According to the general principle of the invention, the displayed instruction may be modified by changing at least one of the symbols, called modifiable symbol, of the instruction, and the display area includes at said at least one modifiable symbol an opening through the front plate and the road sign further includes, on the side of the rear face of the front plate, at least one mobile flat support on which a set of substitution symbols is represented, said front plate and said at least one mobile flat support being parallel to each other, said at least one mobile flat support having a maximum lateral extent comprised within the size of the front plate, wherein each substitution symbol can be brought, by at least one actuator of said at least one mobile flat support, opposite the opening for making it visible from the front of the road sign, and hence creating an instruction display function of said substitution symbol made visible, the mobile flat support or at least one of the mobile flat supports being a disc rotatable about the centre thereof, the centre of the rotatable disc being laterally offset with respect to the centre of the circular front plate.

In order to allow, in the case of the B14-codified road signs, a variable display of the speed that is more surely respected, it is proposed a road sign with a variable display of the speed limit, which is in a traditional shape and hence according to the B14 codification. Moreover, this road sign requires no direct human intervention for changing the display because it is remote controlled and autonomous.

Hence, in the case of the B14-codified road signs, the present invention relates to a device for displaying a speed limitation using a road sign having an aspect according to the B14 codification or equivalent, the road sign including a flat, circular front plate with a front, display face and a rear face, opposite to the front face, the front face of said road sign displaying substantially at the centre thereof, in a speed display area, a numerical value of speed limit, each character of which is of the Arabic numeral type of codified size and typography.

According to the invention, the displayed numerical value may be modified by changing at least one of the characters, called modifiable character, of the numerical value, and the display area includes, at said at least one modifiable character, an opening through the front plate and the road sign further includes, on the side of the rear face of the front plate, at least one mobile flat support on which a set of substitution digits is represented, said front plate and said at least one mobile flat support being parallel to each other, said at least one mobile flat support having a maximum lateral extent comprised within the size of the front plate, wherein each substitution digit can be brought, by at least one actuator of said at least one mobile flat support, opposite the opening for making it visible from the front of the road sign, and hence creating a numerical value display function of said substitution digit made visible, the mobile flat support or at least one of the mobile flat supports being a disc rotatable about the centre thereof, the centre of the rotatable disc being laterally offset with respect to the centre of the circular front plate.

In various embodiments of the invention, the following means, which can be used alone or according to any technically possible combination, are used:

the symbols are pictograms,

the pictograms represent elements chosen among, in particular, a bicycle, a moped, a motorcycle, a car, a truck, a bus, a parking prohibition period, a pattern for switching from a parking prohibition to a stopping prohibition, a road sign display part,

the instruction is a spacing distance, the symbols being numeric characters of the Arabic numeral type and the road sign is codified B17,

the instruction is a speed limitation, the road sign being a B14-codified speed-limitation road sign, the instruction being consisted of several symbols forming a numerical value of speed limitation, the symbols being numeric characters, each numeric character being of the Arabic numeral type, the modifiable symbols being modifiable numeric characters, the substitution symbols being substitution digits, the front face of said road signal displaying, substantially at the centre thereof, in a speed display area, the numerical value of speed limitation, and the road sign further includes, on the side of the rear face of the front plate, said at least one mobile flat support on which a set of substitution digits is represented, said front plate and said at least one mobile flat support being parallel to each other, said at least one mobile flat support having a maximum lateral extent comprised within the size of the front plate, wherein each substitution digit can be brought, by said at least one actuator of said at least one mobile flat support, opposite the opening for making it visible from the front of the road sign, and hence creating a numerical value display function of said substitution digit made visible, the mobile flat support or at least one of the mobile flat supports being a disc rotatable about the centre thereof, the centre of the rotatable disc being laterally offset with respect to the centre of the circular front plate.

the numerical value of speed limitation is expressed in tens (of km/h or miles/h),

the numerical value of speed limitation is expressed in hundreds (of km/h or miles/h),

the tens character of the numerical value of speed limitation is substitutable,

the hundreds character of the numerical value of speed limitation is substitutable,

one of the substitution symbols of the set of substitution symbols is an absence of symbol corresponding to a uniform background colour of the display area,

the road sign includes one mobile flat support per substitution symbol,

the road sign includes one mobile flat support for one sub-set of the substitution symbols,

the road sign includes one mobile flat support for all the substitution symbols,

one of the substitution digits of the set of substitution digits, the hundreds' one, is an absence of digit corresponding to a uniform background colour of the speed display area to allow the display of a numerical value of speed limitation in tens or hundreds,

the road sign includes one mobile flat support per substitution digit,

the road sign includes one mobile flat support for one sub-set of substitution digits,

the road sign includes one mobile flat support for all the substitution digits,

the road sign further includes, on the side of the rear face of the front plate, a fixed flat support including a modifiable character and a second mobile flat support with at least one substitution digit for the modifiable character of the fixed flat support, the second mobile flat support being arranged in front of the fixed flat support, the flat supports being parallel to each other and to the front plate,

the front plate is stiff,

the front plate is a non-metallic plate, including in particular a synthetic material,

the front plate is a metallic plate,

the mobile flat support is stiff,

the mobile flat support is a non-metallic plate, including in particular a synthetic material,

the mobile flat support is a metallic plate,

the front faces of the front plate and of the mobile flat support(s) are reflective,

the actuator is electric and the display device is provided with an autonomous power supply with an electric battery recharged by photovoltaic cells of said device, said device being remote controllable and further including a computer control device, at least one mobile flat support position sensor, and a radio transceiver allowing, on the one hand, receiving commands by radio and, on the other hand, transmitting information, the commands received being at least commands for displaying a determined instruction, in particular a determined speed, and the information transmitted being at least information relating to the display state,

the display device is remote controlled via wireless telecommunication,

the display device further includes a local control means, the computer control device including inputs-outputs with a display and a keyboard,

the display device further includes an electric or optical wireline telecommunication means, the computer control device including inputs-outputs with a wireline link,

the circular flat plate of the road sign includes or forms an antenna,

the rear closing back of the road signal includes or forms an antenna,

the actuator is an electric motor,

the electric motor includes a gear motor,

the actuator is an electromagnet,

the actuation by the electromagnet is bistable, the electromagnet control being able to stay in two distinct stable positions without powering of the magnet,

the road sign includes a single mobile flat support that is a disc rotatable about the centre thereof for all the substitution symbols, in particular substitution digits, each substitution symbol, in particular substitution digit, occupying a proper radial/angular sector of said mobile disc,

the substitution digits are represented on the disc in such an orientation that the height of each digit is substantially perpendicular to the bisectrix of the corresponding radial sector,

in the case of a road sign with a single mobile flat support, the mobile disc is arranged parallel to the plan of the front plate and substantially against the rear face of said front plate,

the road signal includes from the front to the rear, the front plate, a second mobile flat support that is circular and the mobile disc, the second circular flat support being rotatable about the centre thereof and including at least one substitution digit and at least one opening through it, the flat supports being parallel to each other and to the front plate,

the road signal includes from the front to the rear, the front plate, a second mobile flat support, a fixed flat support and the mobile disc, the fixed flat support including a symbol that is modifiable, in particular a numeric character that is modifiable, by masking by a substitution symbol, in particular a substitution digit, of the second mobile flat support, the fixed flat support further including an opening through it for displaying at least one of the substitution symbols, in particular substitution digits, of the mobile disc, the flat supports being parallel to each other and to the front plate,

the second mobile flat support has a proper actuator,

the actuator of the second mobile flat support is an electric motor,

the actuator of the second mobile flat support is an electromagnet,

the second mobile flat support is stiff,

the second mobile flat support is a non-metallic plate, including in particular a synthetic material,

the second mobile flat support is a metallic plate,

the fixed flat support is stiff,

the fixed flat support is a non-metallic plate, including in particular a synthetic material,

the fixed flat support is a metallic plate,

the front faces of the second mobile flat support and of the fixed flat support are reflective,

the mobility of the second mobile flat support is controlled by the rotation of the mobile disc,

the second mobile flat support is scissor mobile and the control thereof by the rotation of the mobile disc is cam-based,

the actuator of the mobile disc is a fixed electric motor driving into rotation a toothed wheel meshing with teeth arranged at the periphery of said mobile disc,

the actuator for rotating the mobile disc is bidirectional, the mobile disc being able to turn in one direction or the other,

the actuator for rotating the mobile disc is unidirectional, the mobile disc always turning in the same direction,

the actuator of the mobile disc is a fixed electromagnet, moving through pulses a driving cam coming into driving engagement with one tooth at a time among teeth arranged on the mobile disc, the mobile disc further including a ratchet mechanism making the rotation thereof unidirectional,

the road sign including a single mobile flat support, herein the mobile disc, is intended for displaying numerical values of speed limitation with exclusively two characters or exclusively three characters,

the road sign including a second mobile flat support, a fixed flat support and the mobile disc, is intended for displaying two- or three-character numerical values of speed limitation,

the mobile disc is integral with the remaining of the road sign, while being free in rotation, through an axis passing through the centre of said mobile disc,

the mobile disc is integral with the remaining of the road sign, while being free in rotation, through, on the one hand, the toothed driving wheel driven by the electric motor and meshing with teeth arranged at the periphery of said mobile disc and, on the other hand, at least two idle toothed wheels, meshing which the teeth arranged at the periphery of said mobile disc, the teethed driving wheel and the at least two idle toothed wheels being distributed over the perimeter of said mobile disc, front and/or rear rails, potentially removable, being possibly applied against one/several parts of the front and/or rear face of the mobile disc,

the mobile disc is integral with the remaining of the road sign, while being free in rotation, through, on the one hand, the toothed driving wheel driven by the electric motor and meshing with teeth arranged at the periphery of said mobile disc and, on the other hand, at least two idle toothed wheels, meshing which the teeth arranged at the periphery of said mobile disc, the teethed driving wheel and the at least two idle toothed wheels being distributed over the perimeter of said mobile disc, the mobile disc being moreover applied, forward, against the rear face of the front plate and, rearward, against a front face of a motor support plate arranged on the rear of said mobile disc, said applications being preferably performed through reduced-friction elements,

one of the substitution digits of the set of substitution digits is an absence of digit corresponding to a uniform background colour of the speed display area,

the mobile flat support position sensor is electro-optic, an electro-optic sensor detecting optically-readable marks on the mobile flat support,

the mobile flat support position sensor is electro-mechanic, a contactor being actuated by at least one indexing finger of the mobile flat support,

the mobile flat support position sensor is electro-mechanic, a flexible-blade contactor being actuated by at least one indexing magnet of the mobile flat support,

the road sign includes a single substitutable character of speed limitation numerical value, said substitutable character being a tens character and the mobile disc including three substitution digits,

the three substitution digits for the tens are a triplet chosen among a combination of three of the following digits: “0” “1” “2” “4” “3” “5” “6” “7” “8” and “9”,

the numerical value of speed limitation that can be displayed is higher than or equal to 100 and the three substitution digits for the tens are a triplet chosen among a combination of three of the following digits: “0” “1” “2” “3”,

the numerical value of speed limitation that can be displayed is higher than or equal to 100 and the three substitution digits for the tens are “0” “1” “3”,

the numerical value of speed limitation that can be displayed is lower than 100 and the three substitution digits for the tens are a triplet chosen among a combination of three of the following digits: “3” “4” “5” “6” “7” “8” and “9”,

the numerical value of speed limitation that can be displayed is lower than 100 and the three substitution digits for the tens are “5” “7” “9”,

the numerical value of speed limitation that can be displayed is lower than 100 and the three substitution digits for the tens are “6” “8” “9”,

the road sign includes two substitutable characters of speed limitation numerical value, said substitutable characters being a hundreds and tens characters and the mobile disc including a set of pairs of substitution digits, each pair including a representation for the tens and a representation for the hundreds,

one of the substitution digits for the hundreds is an absence of character in order to be able to display a numerical value of speed limitation lower than 100,

the mobile disc includes two distinct sets of substitution digits on its two opposite faces and the mobile disc may be mounted in one direction or the other to allow displaying either one of the two sets,

the mobile disc with two distinct sets of substitution digits on its two opposite faces is dismountable et remountable,

in the case of a mobile disc with two distinct sets of substitution digits on its two opposite faces, said at least one mobile flat support position sensor further allows detecting the set intended to be displayed,

the road sign further includes a plate and a rear closing back, the actuator being fixed on the plate and the mobile disc being integral with said plate, while being free in rotation, through an axis passing through the centre of said mobile disc,

on the rear face side of the front plate, the edge of the opening through the front plate includes a strip of flexible material intended to form a gasket between said front plate and the flat support just behind said front plate, in order to reduce the passage of water and/or insects between both,

a flexible scraper is arranged on the rear face side of the front plate to scrape, during the displacements thereof, the surface of the mobile flat support just behind said front plate, in order to eliminate the potential deposits that could have been deposited on said mobile flat support,

the display device further includes at least one monitoring or environment sensor,

the monitoring sensor is chosen among one or several of at least intrusion, impact, inclination, fire detection,

the environment sensor is chosen among one or several of at least temperature, rain, fog, position, illumination, circulation speed (radar), vehicle traffic count detection,

the display device further includes a computer address accessible on a computer network, preferably an INTERNET or INTRANET address on an INTERNET or INTRANET network, and the remote control is made through said computer address on said network,

the wireless remote control for the display device at an INTERNET address implements in particular Wi-Fi® or GSM® or CPRS® or UMTS®, Lora®, Sigfox®, Zigbee®, Bluetooth® remote control,

the remote control implements any suitable protocol as in particular and also TEDI/LCR (“Telecommunications and Information Exchange between Systems/Road Control Language”), Modbus, Diaser, as well any other proprietary or specific protocol,

the display device with wireless remote control further includes a repeater or bridge intended to relay a remote control for another remote display device,

a wireless network is created in a set of display devices connected to each other through their repeaters or bridges,

at least certain of the display devices of the set forming the network are accessible to private users, in particular the maintenance or management personnel circulating on the roads or motorways, who can connect to said network,

at least certain of the display devices of the set forming the network are accessible to the public, in particular the motorists, who can connect to said network.

### ADVANTAGES

The device of the invention responds to the needs of traffic control by modifying temporarily the speed limitation. This may be useful for the management of pollution peaks, the adaptation to unfavourable meteorological conditions, in case of punctual events as a sport or cultural event, works, an anticipation of the road network overloads (holidays departures) or any operation of speed control. It ensures a certain credibility and an impact of the limitation messages displayed. The proposed device moreover offers an economic and easy-to-implement solution for speed limitations. In particular, it does not require civil engineering operations for the connection of a power and communication network because it is autonomous and remote controlled. Moreover, it allows an implantation in lieu of traditional police road signs, with a standard mounting on an existing pole without complementary civil engineering to reinforce the existing base block.

The implementation of an offsetting of the axis of rotation of the mobile disc with respect to the general shape of the road sign is particularly well adapted to complex displays of symbols, only a part of which is substitutable, compared with displays of simples figures or with whole display substitutions.

### DETAILED DESCRIPTION OF AN EXEMPLARY EMBODIMENT

The following description in relation with the appended drawings, given by way of non-limitative examples, will allow a good understanding of what the invention is consisted in and how it may be implemented.

In the appended drawings:

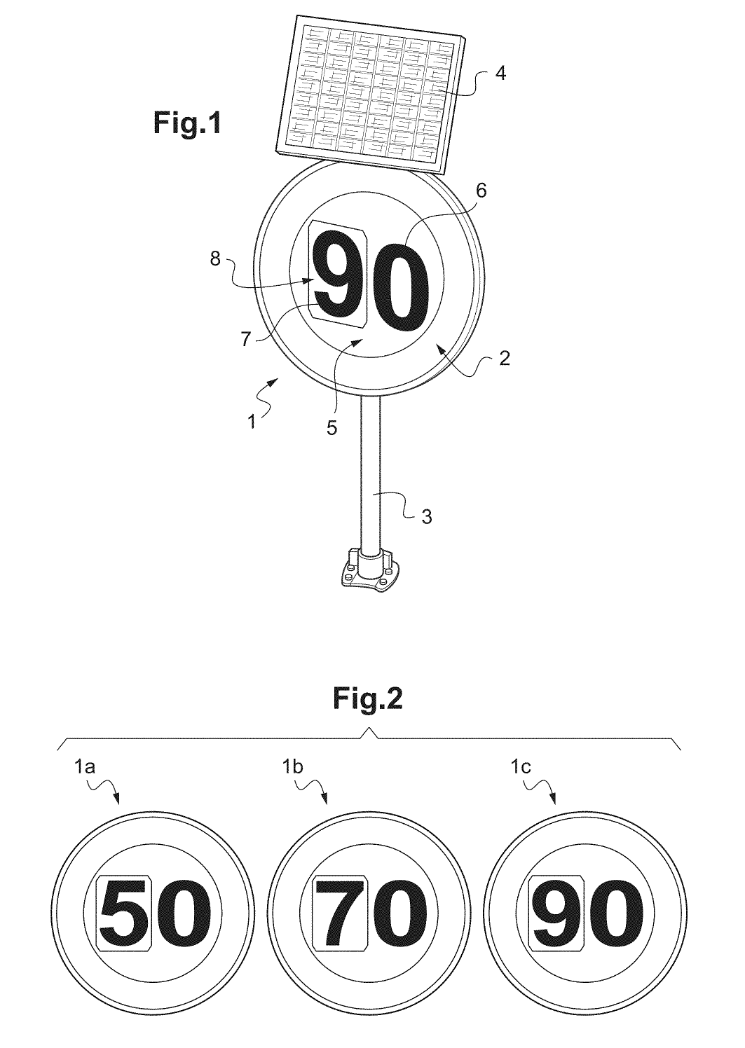

FIG. 1 shows a substantially face view of a first exemplary embodiment of a device according to the invention, allowing a two-digit display,

FIG. 2 shows three possibilities of speed limit display for the road sign of the device of FIG. 1,

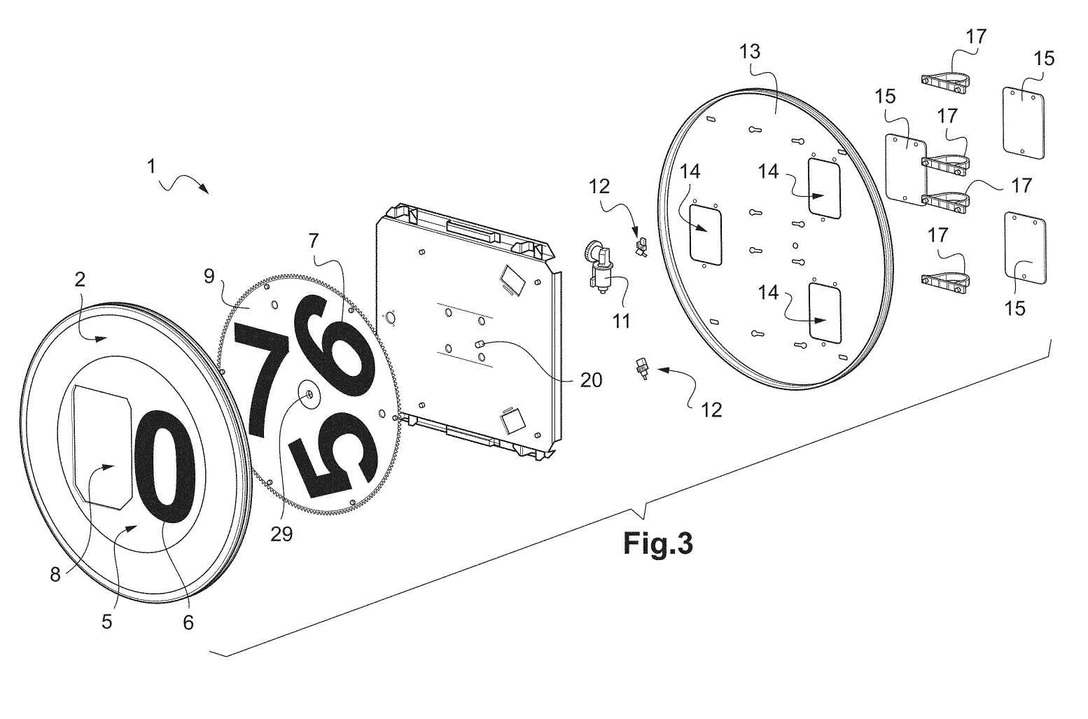

FIG. 3 shows an exploded view of the road sign of the device of FIG. 1,

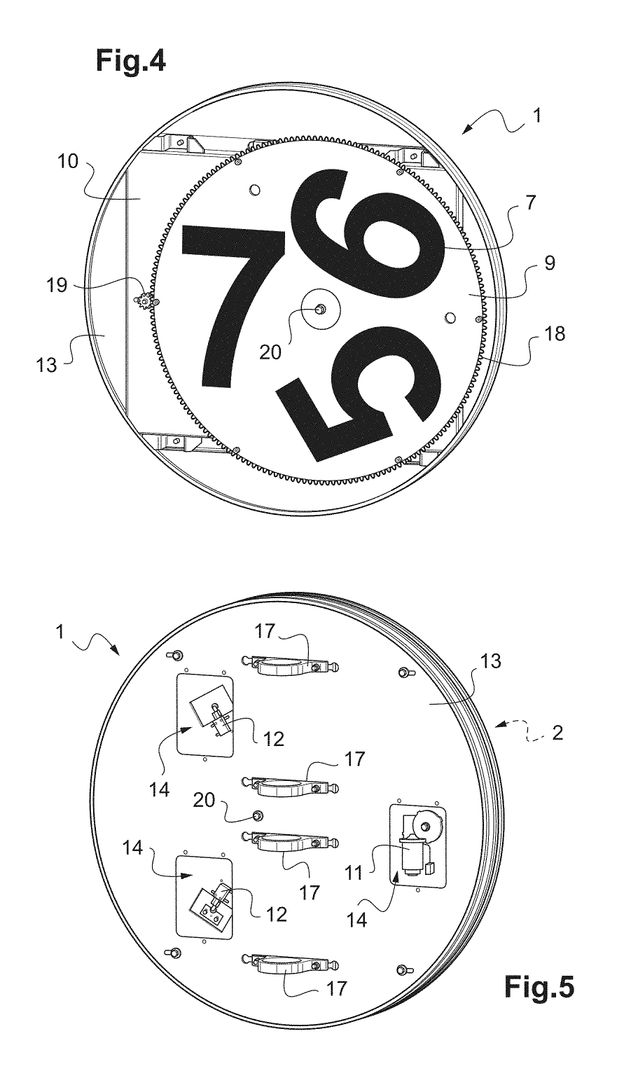

FIG. 4 shows a substantially face view of the road sign of the device of FIG. 1, whose front plate has been removed to allow the visualization of the inner components of said road sign and in particular of the circular mobile flat support on which substitution digits are represented,

FIG. 5 shows a substantially rear view of the road sign of the device of FIG. 1, whose doors for access to inner components have been removed to allow the visualization of some of its inner components and in particular the electric actuator and the position sensors,

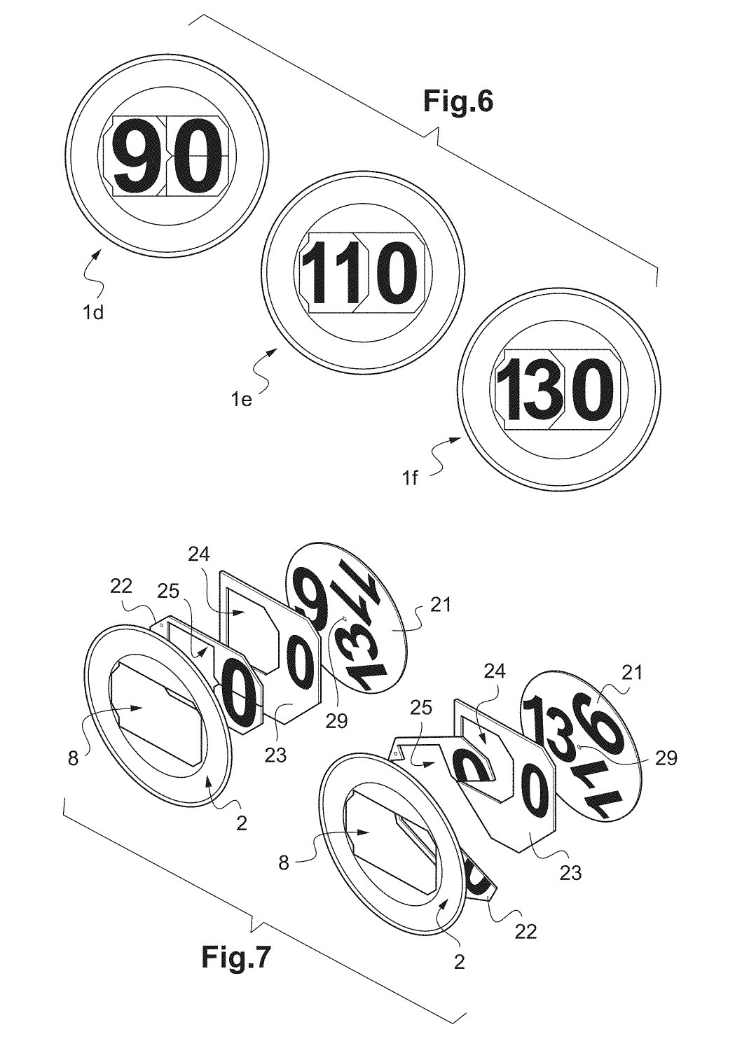

FIG. 6 shows three possibilities of limit speed display for a second exemplary embodiment of a road sign according to the invention, allowing a two- or three-digit display,

FIG. 7 shows two exploded views of a front part of a road sign for two possibilities of limit speed display, in tens or hundreds, for the second exemplary embodiment of the road sign, and

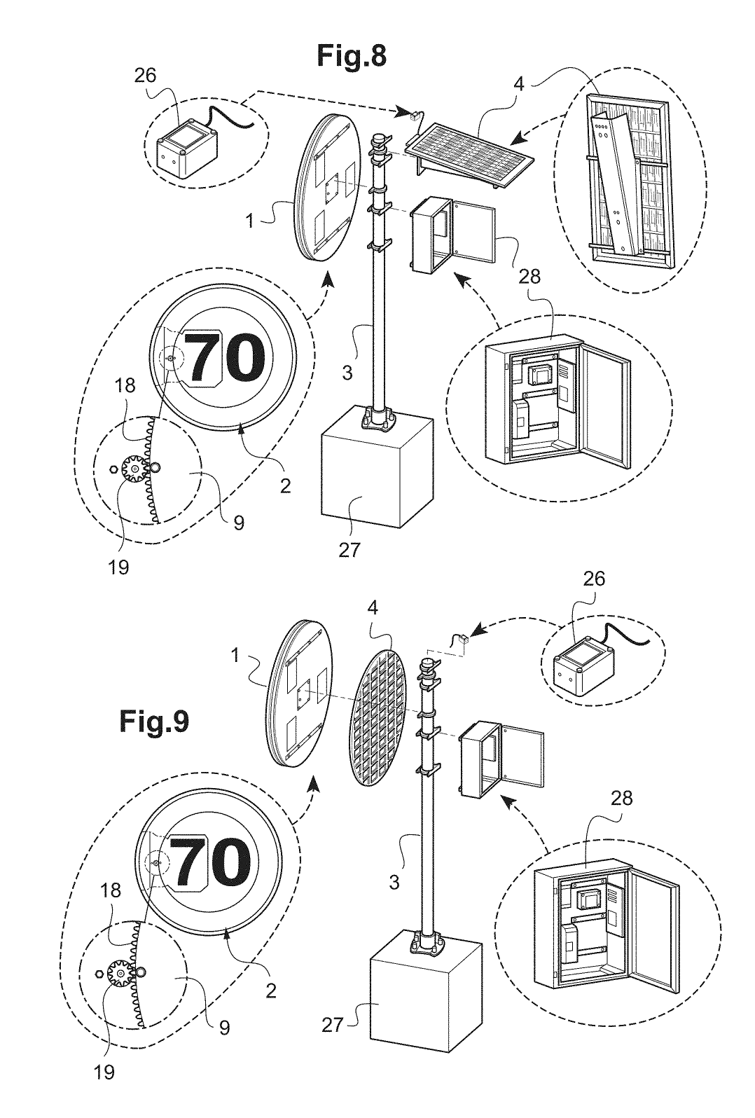

FIGS. 8 to 10 show three examples of implementation of a device according to the invention.

In the following, we will essentially describe in details a device for displaying an instruction, which is a speed limitation, using a B14-codified road sign, the symbols being hence numeric characters in the form of digits.

The road sign of the device of the invention may be made in various ways. Two exemplary embodiments will hence be presented, a first one in which the speed display is two-digit-based and a second one in which the display is two- or three-digit-based.

In its general principle, the road sign device of the invention is based on three main elements: a specific display mechanism, an open and evolving control system and a very reduced power consumption allowing making it fully power autonomous.

Basically, the display system of the road sign is consisted of two main means, possibly repeated: a fixed part and a mobile part, wherein each can be consisted of one or several elements. In the simplest embodiments, the fixed part, called the front plate, is openwork and represents the display area common to all the messages to be displayed. In the case of a police road sign of the B14 type, this part is on the front, essentially flat and circular, and represents the white background, the red ring and the digit “0” for the units. This fixed part is made on the basis of a stiff substrate (sheet) on which a retro-reflective coating is applied. Still in the simplest implementations, the mobile part is a flat mobile disc of circular shape. The latter is made on the basis of a stiff substrate (sheet) on which a retro-reflective coating is applied. In the case of a police road sign of the B14 type, this mobile part represents the different digits of the tens to be displayed in the case of a simple road sign. The mobile part of such a simple road sign is moved by a mechanism that ensures the rotation and the positioning thereof as a function of the digit to be displayed, as well as the holding in position once the desired speed displayed. This mechanism is for example consisted of the following elements:
an actuator, which is a direct current electric motor that generates the mechanical energy for moving the mobile part,
a gear-motor device connected to the motor shaft and that drives a corrugated wheel, and
at least one position sensor to determine the position of the mobile part.

In the case of a disc constituting the mobile part and on which we find the different substitutable digits to be displayed in the opening of the front plate, the mobile disc is free in rotation about its central axis and its periphery is provided with meshing teeth. The corrugated wheel of the gear motor allows driving the disc into rotation by meshing with the teeth of the disc.

It can be noted that the combination of the motor and the gear-motor device allows consuming electric power only when the mobile disc is moved. The gear-motor device also allows holding the disc in stable position when the motor is no longer powered.

Making more complex display sequences, allowing in particular displaying tens or hundreds, may require completing the above mechanism with a second mobile part and a fixed part, to take into account the different letter sizes according to whether two-digit or three-digit limitations are displayed. The second mobile part allows occulting one of the digits, herein the units, and replacing/substituting it.

The first exemplary embodiment in which the speed limitation display is two-digit based will now be described more precisely.

In FIG. 1, the device includes a road sign 1 for displaying speed limitation, which is installed on a pole 3, and a photovoltaic panel 4 including photovoltaic cells is placed above the whole. The road sign 1 includes a circular, flat front plate 2, with a front face including a display area 5. This front plate is a flat metallic plate around which is wound a metallic belt, in particular made of aluminium, in order to form rear return. In variant embodiments, the metallic plate may be stamped in order to form the rearward return at the periphery thereof. We can see two digits in the display area 5, a first digit 6 that is the character “0” (zero) for the units and a second digit 7 that is the character “9” (nine) for the tens, which corresponds to a speed limitation of 90 km/h for the countries using the metric system for speeds. The first digit 6 is fixed and is for example printed or screen printed or, preferably, stuck, on the front plate 2. On the other hand, the second digit 7, which is a substitution digit, appears in a window/opening 8 through the front plate 2, this second digit 7 being itself printed, screen printed or stuck on a mobile flat support 9 of same background colour as that of the front plate 2. It will be seen that this mobile flat support includes several substitution digits that may come individually opposite the window/opening 8 of the front plate. By way of example, the three substitution digits are “5”, “7” and “9” and the three possibilities of variable display are shown 1a, 1b and 1c, respectively, in FIG. 2.

FIG. 3 allows a better understanding of the inner structure and of the operation of the first exemplary embodiment of the road sign. The road sign 1 essentially includes, from the front to the rear, the front plate 2, the mobile flat support 9, herein a mobile disc, a plate 10 and a rear closing back 13. The window/opening 8 of the front plate 2 is most visible therein. The mobile flat support, which is circular, forms a mobile disc 9 rotating about the centre thereof and supports a set of three substitution digits 7, herein “5”, “7” and “9”, each substitution digit occupying a proper radial/angular sector of the flat support. The axis of rotation 20 of the mobile disc 9 is connected to the plate 10. The back 13 is a flat metallic plate around which is wound a metallic belt, in particular made of aluminium, in order to form a forward return. In variant embodiments, the metallic plate may be stamped in order to include the forward return at the periphery thereof. The return of the front plate 2 and return of the back 13 are partially overlapping so that the road sign 1 can be closed at the circular periphery thereof.

The rear closing lid 13 includes openings 14 closed by access doors/flaps 15 and allowing acceding to inner components of the road sign. These inner components are in particular the gear-motor electric actuator 11 and position sensors 12 for the mobile disc 9. The plate 10 that is fixed to the closing back 13 allows fixing the electric actuator 11 and the position sensors 12 as well as, possibly, other devices (not shown) as, in particular, a computer control device, a radio transceiver and an electric battery that is recharged by the photovoltaic panel 4. Fixation and clamping collars 17 installed on the rear face of the back 13 allow the fixation to the pole 3.

As visible in FIG. 4, the assembly of the back 13, the plate 10 and the mobile disc 9 and other elements useful for the operation of the road sign forms a proper operational part and the front plate 2, which is essentially passive, is fixed thereon. The fixation between both may be made at the returns, the forward one on the back and the rearward one on the front plate. As a complement or as an alternative, this fixation of the front plate may be made through the plate or through ad-hoc inner fixation elements.

Still in FIG. 4, we can see the means for driving the mobile disc 9 into rotation, the latter including teeth 18 at the periphery thereof, which mesh with a toothed wheel 19 driven by the electric actuator 11, which is herein an electric rotary motor of the gear motor and angle transmission type. Position indexing means allow the sensors to determine the position of the mobile disc 9, or at least, to determine when said mobile disc has reached a determined position corresponding to the display of a determined substitution digit. These coding means are, for example, digits acting on an electromagnetic contact of a position sensor.

FIG. 5 shows, viewed from the rear, the road sign 1 assembled. The openings 14 of the road sign back 13 are open, the access doors/flaps 15 having been removed, and the electric actuator 11 and the position sensors 12 can be seen therein.

A second exemplary embodiment allowing displaying the speed limitation in tens or in hundreds will now be presented. Three display possibilities are shown on the road sign of FIG. 6, with for 1d “90”, 1e “110” and 1f “130”. We can observe that, in any case, the regulatory format of the digits is respected.

As can be seen in FIG. 7, in which only the circular flat front plate 2 and the different flat supports 21, 22, 23 are represented to simplify the explanations, and as in the two-digit embodiment described hereinabove, a circular mobile flat support 21, or mobile disc, is implemented. This circular mobile flat support 21, also called mobile disc, is the most on the rear. The substitution digits that are represented on this mobile disc 21 relate this time to tens and hundreds and are hence of different formats according to whether the related speed limitation is in hundreds or in tens of km/h (or miles/h). Given that the format is different according to the limitation, it is also provided that the unit digit, herein a zero, can be substituted, not in value because it stays a zero, but in format. For that purpose, a second mobile flat support 22 with a zero in a first format is implemented. This second mobile flat support 22, the most on the front among the mobile flat supports, is herein scissor mobile to cover or not the unit zero in a first format of a fixed flat support 23 and to substitute thereto a zero in another format. The fixed flat support 23 is hence taken in sandwich between the second mobile flat support 22 and the mobile disc 21. The moving of this scissor-mobile second flat support 22 is ensured by a cam system arranged on the mobile disc 21, this cam system being preferably positioned on the rotation support axis of said circular mobile flat support 21. That way, there is no need for a specific motor to actuate this scissor-mobile second flat support 22 and this is the same motor+gear motor that ensures the two mobilities of the two mobile flat supports. The scissor-mobile second flat support 22 behaves as a jaw that opens and closes in a plan as a function of the shape and position of the cam.

Other types of mobilities of this second mobile flat support may however be implemented, for example, a single or double vertical slider mobility or a more complex translation of the iris diaphragm type. In any case, the circular mobile flat support 21 and the second mobile flat support 22 (in this example, scissor-mobile) are mobile in plans that are parallel to each other and to the front face of the road sign and to the fixed flat support 23. Windows/openings, 8, 25 and 24, respectively, are made through the front plate 2, the second mobile flat support 22 and the fixed flat support 23 so as to allow the correct display according to the various possible substitutions.

In the road sign device of the invention, the mechanism allowing the moving of the mobile flat support(s) is piloted by a computer control device made in the form of an electronic card that ensures all the control and command functions. Moreover, the device is power autonomous and includes a power-storage battery that is recharged by an electric generator consisted of photovoltaic cells. Optionally, a wind turbine may complete the recharging means.

In FIGS. 8 to 10, the autonomous display device 1 is schematised in exploded view and with detail inserts, with three examples of implementation of photovoltaic cells.

In these FIGS. 8 to 10, the road sign 1 is intended to be mounted on the front of a pole 3, which is herein fixed to a concrete base block 27. On the rear of the pole 2 is fixed, substantially at the height of the road sign 1, an electrical cabinet 28 containing the electronic/computer equipment of the device of the invention. In said cabinet 28 is found in particular a rechargeable battery, a regulator for the battery charge and for the display device supply, a computer control device or control card and a radio transceiver or, more generally, a communication device. Moreover, a solar/photovoltaic panel 4 consisted of photovoltaic cells is fixed in upper part of the display device. It is to be noted that, in other modes of implementation, a part or all the content of the electric cabinet may be incorporated in the display road sign 1 itself, said electric cabinet itself being then omitted from the device. Finally, to show that the device may further incorporate one or several other sensors than the position sensor(s) for the mobile flat support(s), in particular environment, positioning (GPS), safety (impact, inclination, intrusion, theft, displacement, fire . . . ) sensors, a sensor 26 has been installed towards the top of the pole 3. This sensor is for example a rain sensor. It is to be understood that the sensor(s) may be arranged at other places of the device, and for example in the electric cabinet or in the road sign itself.

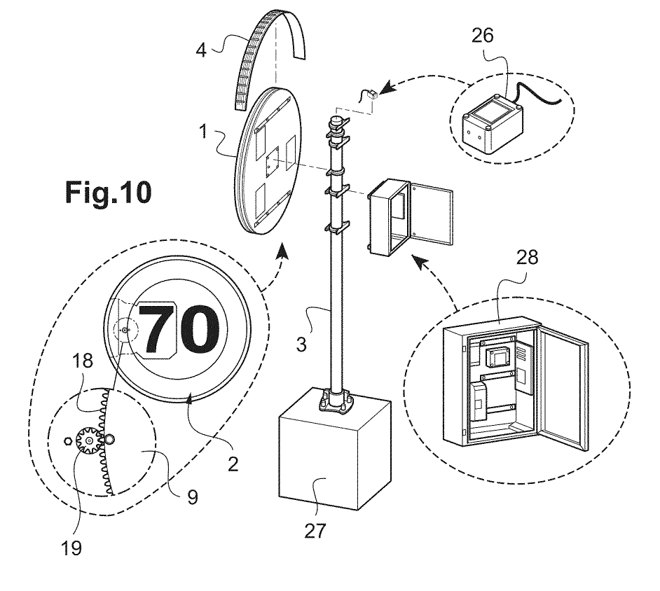

In FIG. 8, the photovoltaic panel is a substantially flat rectangular element mounted on the rear of the pole and slightly inclined with respect to the horizontal in order to improve the light picking up. In FIG. 9, the photovoltaic panel is a substantially flat circular element mounted on the rear of the road sign. In FIG. 10, the photovoltaic panel is a strip-like flexible element mounted on the upper periphery of the road sign. It will be understood that, even if certain of the examples of position of the photovoltaic panel do not allow obtaining optimum throughputs in light picking up, this is not really an obstacle for the operation of the device of the invention, given the low mean consumption thereof.

Indeed, the whole display device of the invention is designed to reduce maximally the power consumption: no power consumption by the positioning mechanism when the latter is in rest, an optimized, low-consumption, computer control device, communication system and active sensors supplied according to the needs, passive sensors, etc. . . . . The electric power is stored in a rechargeable battery that ensures the operation of the road sign in the absence of solar radiation and allows peaks of consumption.

An example of basic operation of the display road sign device with a remote control, in particular of the radio type, will now be described. However, it is possible to control locally/directly the road sign from the computer control device thereof that includes a local input/output interface including in particular simplified display and keyboard. The display device, thanks to its computer control device, has a unique, proper identifier (reference number or computer address or WEB address), that serves, during the radio exchanges or other, to command and control specifically each road sign. The computer control device that is connected to a radio transceiver and to sensors, is configured to receive instructions by radio, in particular instructions for displaying a determined speed. The computer control device is provided with a specific software that allows managing the movements as a function of the instructions received. The states of the positions sensors of the mobile flat supports inform the computer control device about the current display and whether the flat support(s) are in a correct/reached display position or not. As a function of the display instruction received and of the current display, the computer control device will control the electric actuator to obtain the required display. Once this required display obtained, the road sign will confirm by a radio transmission the good implementation of the instruction. Preferably, the computer control device determines the direction of rotation to be applied to the circular mobile flat support to pass the most rapidly/economically possible from the initial display to the new display, then to control the motor consequently. Preferably, the position sensors are activated when the mobile flat support has reached the desired position. The states of these sensors are forwarded to the computer control device that then stops the power supply of the motor, due to the fact that the desired position for the required display has been reached.

By way of safety, a timer may be started when the display instruction is received and, if the required display cannot be obtained at the end of the timer delay, the motor supply may be stopped and a radio transmission is emitted to inform about an error. Hence, the sensors, in association with the specific software of the computer control device, allow determining at any time the position of the mobile flat support or of the mobile flat supports. In the example of FIG. 7, the positions of all the mobile flat supports 21, 22 are determined by the position of the mobile disc 21 because they are functionally integral with each other, the mobile disc 21 driving the other ones 22. It is also possible to detect anomalies such that a position that is not reached despite a command of the motor. The detection of such anomalies allows the system to switch to a safety mode (in particular, stop of the power supply of the motor) and to send back an error message by radio transmission when the display instruction has been transmitted by radio.

Preferably, an instruction for requesting the road sign state is sent before the display instruction and this state request instruction causes the transmission, by the road sign, of information relating to the operational state of the road sign, for example: road sign operational or not, charge level of the battery, current display, presence of an anomaly, type of anomaly . . . in order to avoid the sending of a display instruction if the road cannot execute it. It is understood that if no answer to this state request instruction is obtained from the road sign, it corresponds to a major breakdown, for example an absence of electric power supply. Preventive maintenance may also be implemented, the road sign transmitting an alert if it detects an anomaly or a beginning of anomaly, for example a battery charge holding decreasing despite a sufficient sunlight, an unfavourable development of operation parameters, an excessive consumption by the electric actuator.

The road sign may hence be connected by radio to a communication device that hence allow a remote piloting. The road sign is pilotable via all the existing or future communication systems (GPS, GPRS, UMTS, Wifi, Bluetooth, Lora, SigFox, Zigbee . . . ). It may however be provided among the inputs/outputs of the computer control device, one or several electric or optical wire links allowing a remote piloting, or even a local piloting by a portable terminal brought by an operator, through wire or fibre-optic links: RS232, RS485, Modem, Ethernet.

Preferably, the remote piloting is performed according to two operation principles, which may be used independently or simultaneously:
A piloting by supervision: in this case, the road sign is viewed from a component supervising it as a “slave” device. The supervising component sends positioning instructions that are executed by the road sign. In return, the road sign sends back information relating to the display as well as, possibly, any other information relating to the operation of the road sign: anomalies, battery level, states of the different sensors liable to be connected thereto.
A piloting by an integrated “Web” server: in this case, a “Web” server is integrated to the computer control device of the road sign and provides a user interface that allows a remote piloting by means of a user-friendly interface and requires no specific supervision component. Any type of terminal with a browser is hence able to remote pilot the road sign (smartphone, tablet, PC . . . ). The computer accesses to the road sign are secured thanks to the implementation of a connection procedure using a road sign identifier (specific identifier and/or specific network address), a user name and a password. In the same way as in the case of a piloting by a supervision component, the road sign is able to provide information relating to the display as well as, possibly, any other information relating to the operation of the road sign: anomalies, battery level, states of the different sensors liable to be connected thereto.

It is to be noted that if, preferably, the radio exchanges with several road signs are performed in star configuration, i.e. between a single central control node and directly towards each road sign forming a terminal point, it is also possible to implement network exchanges, each road sign forming a relay point from the network towards another relay or terminal road sign and, in return, from the terminal point road sign towards another relay road sign or the central control node.

Typically, the computer control device is configured to communicate according to a protocol of the “INTERNET” type on the “WEB” or any other suitable protocol as TEDI/LCR (“Telecommunications and Information Exchange between Systems/Road Control Language”), UMTS, NTC/IP, Modbus, Diaser, as well as any other proprietary protocol, specific to supervision device providers. Safety solutions using passwords and encryption of the data transmitted are implemented for the communications. The transmission/reception operations are performed through a proprietary or generic modem, as for the transmission and reception means.

A vandalism, theft and/or impact detector may also be implemented in the road sign or, more generally, in the display device, a detection causing the emission of an alert. Hence, the display device may be provided with monitoring sensors (called that way to be differentiated from the position sensor(s) for the mobile flat support(s)), detecting for example the loss of verticality and allowing the emission of an alert in the case where the road sign would have undergone an impact causing a displacement from its support. Other types of detection are possible. The emission of this alert allows the operator to organize at best and within the shortest delay the maintenance operations required to repairing the road sign.

Similarly, the road sign may be provided with other types of sensors, called environment sensors to be differentiated from the position sensor(s) for the mobile flat support(s), for example a rain, temperature, pollution, light (the photovoltaic cells being however able to play this role) sensor, etc. . . . . A specific software of the computer control device analyses in continuous the state of these sensors and, as a function of the information collected, including these states, and of predefined piloting strategies, the software generates automatically and hence locally different commands for positioning/display of the speed limitations.

The different possibilities of implementation described above may be declined according to various non-limitative variants:
Autonomous and isolated operation. The road sign operates in an autonomous and isolated manner. As a function of the information collected by its sensor(s), it determines autonomously the message to be displayed. This mode of operation also allows the connection to a remote monitoring component (supervision, web server).
Cluster operation. Several road signs are arranged on a road section. One of the road sign is provided with environment sensors and plays the role of a master, the other road signs reacting as a function of the position commands communicated by the master road sign. The transfer of information between the different road signs may be performed by means of any type of media (radio, infrared, laser, wire, optical fibre). This mode of operation also allows the connection to a remote monitoring component (supervision, web server).
Piloting by supervision and sensors. This mode of operation combines the operation by supervision and by environment sensor(s). It may relate to an isolated road sign or a clustered road sign system. The display actuation is then controlled by priority rules between the different sources of instructions, i.e. the sensors (local decision) and the supervision components (instruction from remote origin)

The display device of the invention may be positioned fixedly and permanently on the road network or in a mobile and temporary manner in the case of temporary situations: works, sport or cultural events. The display device may also be provided with a GPS component that allows knowing accurately the position thereof on the road network. The transmission of this position information to a remote supervision component allows obtaining the following benefits in case of fixed and mobile installations: ensuring an autonomous wealth management, organizing efficiently the potential maintenance operations by localizing accurately the device and integrating easily the equipment in a supervision synoptic.

The present invention may be applied to other types of road signs than B14 and, for example, to a B17 instruction road sign for a spacing distance between vehicles, the symbols remaining numeric characters of the Arabic numeral type. It may be applied to B6a2 and B6a3 road signs with digits corresponding to periods/dates that can tilt/pass to either side (top right to bottom left) of the road sign or, for a same side of the road sign, to periods/dates that can change. In this latter example, one of the substitutable symbols can be an absence of symbol corresponding to the plain background of the display area. The invention may be applied equivalently to B25, B33 or B43-codified road signs. Moreover, a road sign with a circular front plate has been described, but the invention may be applied by equivalence to a road sign with a square or rectangular front plate, the mobile and possibly fixed flat support(s) being configured to remain within the size of the front plate. Finally, the registered trademarks mentioned belong to their respective owners.

1-11. (canceled)

12. A device for displaying an instruction using an instruction road sign (1) having an aspect according to the B codification or equivalent, the road sign (1) including a flat, circular front plate (2) with a front, display face and a rear face, opposite to the front face, the front face of said road sign displaying substantially at the centre thereof, in an instruction display area (5), an instruction consisted of several symbols of codified size and typography,
wherein the displayed instruction may be modified by changing at least one of the symbols, called modifiable symbol, of the instruction, and
wherein the display area (5) includes at said at least one modifiable symbol an opening (8) through the front plate and
wherein the road sign further includes, on the side of the rear face of the front plate (2), at least one mobile flat support (9) (21) (22) on which a set of substitution symbols (7) is represented, said front plate (2) and said at least one mobile flat support (9) (21) (22) being parallel to each other, said at least one mobile flat support (9) (21) (22) having a maximum lateral extent comprised within the size of the front plate (2), wherein each substitution symbol can be brought, by at least one actuator (11) of said at least one mobile flat support (9) (21) (22), opposite the opening (8) for making it visible from the front of the road sign, and hence creating an instruction display function of said substitution symbol made visible, the mobile flat support or at least one of the mobile flat supports being a disc (9) (21) rotatable about the centre thereof, the centre (29) of the rotatable disc (9) (21) being laterally offset with respect to the centre of the circular front plate (2).

13. The display device according to claim 12, wherein the instruction is a speed limitation, the road sign being a B14-codified speed limitation road sign (1), the instruction being consisted of several symbols forming a numerical value of speed limitation, the symbols being numeric characters, each numeric character being of the Arabic numeral type (6) (7), the modifiable symbols being modifiable numeric characters, the substitution symbols being substitution digits,
the front face of said road sign displaying, substantially at the centre thereof, in a speed display area (5), the numerical value of speed limitation, and
wherein the road sign further includes, on the side of the rear face of the front plate (2), at least one mobile flat support (9) (21) (22) on which a set of substitution digits (7) is represented, said front plate (2) and said at least one mobile flat support (9) (21) (22) being parallel to each other, said at least one mobile flat support (9) (21) (22) having a maximum lateral extent comprised within the size of the front plate (2), wherein each substitution digit can be brought, by at least one actuator (11) of said at least one mobile flat support (9) (21) (22), opposite the opening (8) for making it visible from the front of the road sign, and hence creating an instruction display function of said substitution digit made visible, the mobile flat support or at least one of the mobile flat supports being a disc (9) (21) rotatable about the centre thereof, the centre (29) of the rotatable disc (9) (21) being laterally offset with respect to the centre of the circular front plate (2).

14. The display device according to claim 12, wherein the actuator (11) is electric and the display device is provided with an autonomous power supply with an electric battery recharged by photovoltaic cells (4) of said device, said device being remote controllable and further including a computer control device, at least one mobile flat support position sensor (12), and a radio transceiver allowing both receiving commands by radio, as well as transmitting information, the commands received being at least commands for displaying a determined instruction, and the information transmitted being at least information relating to the display state.

15. The display device according to claim 14, wherein the determined instruction is a determined speed to display.

16. The display device according to claim 12, wherein the road sign (1) includes a single mobile flat support that is a disc (9) rotatable about the centre (29) thereof for all the substitution symbols, each substitution symbol occupying a proper radial/angular sector of said mobile disc.

17. The display device according to claim 16, wherein the substitution symbols are substitution digits (7).

18. The display device according to claim 12, wherein the road sign (1) includes, from the front to the rear, the front plate (2), a second mobile flat support (22), a fixed flat support (23) and the mobile disc (21), the fixed flat support (23) including a symbol that is modifiable by masking by a substitution symbol, the second mobile flat support (22), the fixed flat support (23) further including an opening (24) through it for displaying at least one of the substitution symbols, of the mobile disc (21), the flat supports (21, 22, 23) being parallel to each other and to the front plate (2).

19. The display device according to claim 18, wherein the symbol that is modifiable is a numeric character that is modifiable by masking by a substitution symbol that is a substitution digit.

20. The display device according to claim 18, wherein the mobility of the second mobile flat support (22) is controlled by the rotation of the mobile disc (21).

21. The display device according to claim 20, wherein the second mobile flat support (22) is scissor mobile and the control thereof by the rotation of the mobile disc (21) is cam-based.

22. The display device according to claim 16, wherein the actuator (11) of the mobile disc (9) is a fixed electric motor driving into rotation a toothed wheel (19) meshing with teeth (18) arranged at the periphery of said mobile disc (9).

23. The display device according to claim 18, wherein the actuator (11) of the mobile disc (21) is a fixed electric motor driving into rotation a toothed wheel (19) meshing with teeth (18) arranged at the periphery of said mobile disc (21).

24. The display device according to claim 12, wherein the road sign (1) further includes a plate (10) and a rear closing back (13), the actuator (11) being fixed to the plate and the mobile disc (9) (21) being integral with said plate (10), while being free in rotation, through an axis (20) passing through the centre (29) of said mobile disc.

25. The display device according to claim 14, further comprising at least one surveillance or environment sensor (26).

26. The display device according to claim 14, further comprising a computer address accessible on the computer network, and wherein the remote control is made through said computer address on said network.

27. The display device of claim 26, wherein the computer network is an INTERNET or INTRANET address on an INTERNET or INTRANET network.
